(19) United States
(12) Patent Application Publication
(10) Pub. No.: US 2025/0365957 A1
(43) Pub. Date: Nov. 27, 2025

(54) SEMICONDUCTOR MEMORY DEVICE INCLUDING THREE-DIMENSIONALLY ARRANGED MEMORY CELLS AND ELECTRONIC SYSTEM INCLUDING THE SAME

(71) Applicant: SAMSUNG ELECTRONICS CO., LTD., SUWON-SI (KR)

(72) Inventors: Ju Hyung KIM, Suwon-si (KR); Wan Ki KIM, Suwon-si (KR)

(21) Appl. No.: 18/889,604

(22) Filed: Sep. 19, 2024

(30) Foreign Application Priority Data
May 24, 2024 (KR) 10-2024-0067522

(51) Int. Cl. H10B 43/27; G11C 16/04; H01L 25/065; H10B 43/10; H10B 43/35; H10B 43/40; H10B 80/00

(52) U.S. Cl. CPC H10B 43/27; G11C 16/0483; H01L 25/0652; H10B 43/10; H10B 43/35; H10B 43/40; H10B 80/00; H01L 2225/06506

(57) ABSTRACT

A semiconductor memory device includes: a substrate; a stack structure disposed on the substrate, wherein the stack structure includes a plurality of gate electrodes stacked on each other; and a channel structure disposed in the stack structure and penetrating the plurality of gate electrodes, wherein the channel structure includes: a conductive pillar extending in a first direction; a channel film disposed between the plurality of gate electrodes and the conductive pillar and extending in the first direction; a first interfacial film interposed between the conductive pillar and the channel film and extending in the first direction; a first data storage film interposed between the conductive pillar and the first interfacial film and extending in the first direction; and a second data storage film interposed between each of the gate electrodes and the channel film and extending in the first direction.

### CROSS-REFERENCE TO RELATED APPLICATION

This application claims priority under 35 USC § 119 to Korean Patent Application No. 10-2024-0067522 filed on May 24, 2024 in the Korean Intellectual Property Office, the disclosure of which is incorporated by reference herein in its entirety.

### TECHNICAL FIELD

The present inventive concept relates to a semiconductor memory device, and an electronic system including the same. More specifically, the present inventive concept relates to a semiconductor memory device including three-dimensionally arranged memory cells, and an electronic system including the same.

### DISCUSSION OF THE RELATED ART

As the electronics industry continues to develop, semiconductor memory devices that are capable of storing a high capacity of data therein is becoming increasingly desirable for electronic systems. Accordingly, a semiconductor memory device including memory cells that are arranged in a three-dimensional manner instead of memory cells arranged in a two-dimensional manner are currently under development for increasing the data storage capacity of the semiconductor memory device.

### SUMMARY

According to embodiments of the present inventive concept, a semiconductor memory device includes: a substrate; a stack structure disposed on the substrate, wherein the stack structure includes a plurality of gate electrodes stacked on each other and spaced apart from each other; and a channel structure disposed in the stack structure and penetrating the plurality of gate electrodes, wherein the channel structure includes: a conductive pillar extending in a first direction that is substantially perpendicular to an upper surface of the substrate; a channel film disposed between the plurality of gate electrodes and the conductive pillar and extending in the first direction; a first interfacial film interposed between the conductive pillar and the channel film and extending in the first direction; a first data storage film interposed between the conductive pillar and the first interfacial film and extending in the first direction; and a second data storage film interposed between each of the gate electrodes and the channel film and extending in the first direction.

According to embodiments of the present inventive concept, a semiconductor memory device includes: a peripheral circuit structure including a peripheral circuit substrate and a peripheral circuit element disposed on the peripheral circuit substrate; a source layer including a first surface, which faces the peripheral circuit structure, and a second surface that is opposite to the first surface; a stack structure disposed on the source layer, wherein the stack structure includes a plurality of gate electrodes stacked on top of each other and spaced apart from each other in a first direction that is substantially perpendicular to the first surface; and a channel structure disposed on the source layer and intersecting the plurality of gate electrodes, wherein the channel structure includes: a conductive pillar extending in the first direction; a channel film disposed between the plurality of gate electrodes and the conductive pillar and extending in the first direction; a first data storage film interposed between the conductive pillar and the channel film and extending in the first direction; a first interfacial film interposed between the channel film and the first data storage film and extending in the first direction; a second interfacial film interposed between the plurality of gate electrodes and the channel film and extending in the first direction; and a second data storage film interposed between the plurality of gate electrodes and the second interfacial film and extending in the first direction, wherein the first data storage film includes at least one of a ferroelectric film or an electrolyte film.

According to embodiments of the present inventive concept, an electronic system includes: a main substrate; a semiconductor memory device including a peripheral circuit structure and a cell structure sequentially stacked on the main substrate; and a controller disposed on the main substrate and electrically connected to the semiconductor memory device, wherein the cell structure includes: a stack structure including a plurality of gate electrodes sequentially stacked on each other and spaced apart from each other in a first direction; a channel structure disposed in the stack structure and penetrating the plurality of gate electrodes, wherein the channel structure includes: a conductive pillar extending in the first direction; a channel film disposed between the plurality of gate electrodes and the conductive pillar and extending in the first direction; a first interfacial film interposed between the conductive pillar and the channel film and extending in the first direction; a second interfacial film interposed between the plurality of gate electrodes and the channel film and extending in the first direction; a first data storage film interposed between the conductive pillar and the first interfacial film and extending in the first direction; and a second data storage film interposed between the plurality of gate electrodes and the second interfacial film and extending in the first direction.

### BRIEF DESCRIPTION OF DRAWINGS

The above and other aspects and features of the present inventive concept will become more apparent by describing in detail embodiments thereof with reference to the attached drawings, in which:

FIG. 1 is an illustrative block diagram for illustrating a semiconductor memory device according to embodiments of the present inventive concept.

FIG. 2 is an example circuit diagram for illustrating a semiconductor memory device according to embodiments of the present inventive concept.

FIG. 3 is a layout diagram for illustrating a semiconductor memory device according to embodiments of the present inventive concept.

FIG. 4 is a cross-sectional view cut along A-A in FIG. 3.

FIG. 5 is an enlarged view illustrating a Q area of FIG. 4.

FIG. 6 is a diagram illustrating a semiconductor memory device according to embodiments of the present inventive concept.

FIG. 7 is a diagram illustrating a semiconductor memory device according to embodiments of the present inventive concept.

FIGS. 8, 9, 10, 11, 12, 13, 14, 15, 16, 17, 18, and 19 are diagrams of intermediate structures corresponding to intermediate steps of a method for manufacturing a semiconductor memory device in accordance with embodiments of the present inventive concept.

FIG. 20 is an example block diagram illustrating an electronic system according to embodiments of the present inventive concept.

FIG. 21 is an example perspective view illustrating an electronic system according to embodiments of the present inventive concept.

FIG. 22 is a schematic cross-sectional view cut along I-I in FIG. 21.

### DETAILED DESCRIPTION OF THE EMBODIMENTS

It will be understood that, although the terms “first”, “second”, etc. may be used herein to describe various elements, components, regions, layers and/or sections, these elements, components, regions, layers and/or sections should not be limited by these terms. These terms are only used to distinguish one element, component, region, layer or section from another element, component, region, layer or section. Thus, a first element, component, region, layer or section discussed below could be termed a second element, component, region, layer or section without departing from the spirit and scope of the present inventive concept.

Spatially relative terms, such as “beneath,” “below,” “lower,” “above,” “upper” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, in the example, terms “below” and “beneath” may encompass both an orientation of above, below and beneath. The device may be otherwise oriented (e.g., rotated 90 degrees or at other orientations) and the spatially relative descriptors used herein may be interpreted accordingly.

Hereinafter, embodiments of the present inventive concept are described in detail with reference to the attached drawings. The same reference numerals are used for the same components in the drawings and specification, and duplicate descriptions thereof are omitted or briefly discussed.

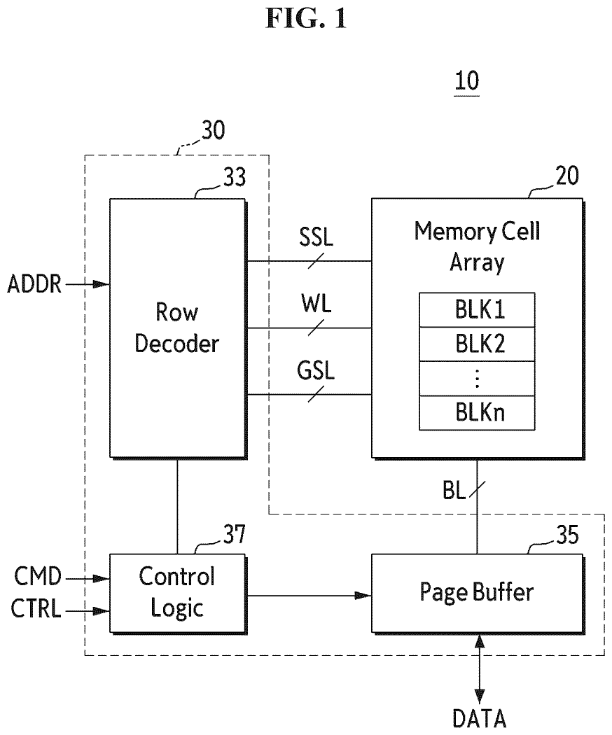

Hereinafter, referring to FIG. 1 to FIG. 7, a semiconductor memory device according to embodiments of the present inventive concept is described.

FIG. 1 is an illustrative block diagram for illustrating a semiconductor memory device according to embodiments of the present inventive concept.

The memory cell array 20 may include a plurality of memory cell blocks BLK1 to BLKn. Each of the memory cell blocks BLK1 to BLKn may include a plurality of memory cells. The memory cell array 20 may be connected to the peripheral circuit 30 via a bit-line BL, a word-line WL, at least one string select line SSL, and at least one ground select line GSL. For example, the memory cell blocks BLK1 to BLKn may be connected to a row decoder 33 via the word-line WL, the string select line SSL and the ground select line GSL. Further, the memory cell blocks BLK1 to BLKn may be connected to a page buffer 35 via the bit-line BL.

The peripheral circuit 30 may receive an address ADDR, a command CMD, and a control signal CTRL from an external device to the semiconductor memory device 10, and may transmit and receive data DATA to and from an external device to the semiconductor memory device 10. The peripheral circuit 30 may include a control logic 37, the row decoder 33, and the page buffer 35. The peripheral circuit 30 may further include various sub-circuits such as an input/output circuit, a voltage generation circuit for generating various voltages required for an operation of the semiconductor memory device 10, and an error correction circuit for correcting an error of the data DATA read from the memory cell array 20.

The control logic 37 may be connected to the row decoder 33, the input/output circuit, and the voltage generation circuit. The control logic 37 may control overall operations of the semiconductor memory device 10. The control logic 37 may generate various internal control signals used in the semiconductor memory device 10 in response to the control signal CTRL. For example, the control logic 37 may adjust a voltage level of a voltage supplied to the word-line WL and the bit-line BL when performing a memory operation such as a program operation or an erase operation.

The row decoder 33 may select at least one of the plurality of memory cell blocks BLK1 to BLKn in response to the address ADDR, and may select at least one word-line WL, at least one string select line SSL, and at least one ground select line GSL of the selected at least one memory cell block BLK1 to BLKn. Further, the row decoder 33 may transmit a voltage for performing a memory operation to the word-line WL of the selected at least one memory cell block BLK1 to BLKn.

The page buffer 35 may be connected to the memory cell array 20 via the bit-line BL. The page buffer 35 may operate as a writer driver or a sense amplifier. For example, when performing a program operation, the page buffer 35 operates as the writer driver to apply a voltage based on the data DATA to be stored in the memory cell array 20 to the bit-line BL. In addition, when performing a read operation, the page buffer 35 may operate as the sense amplifier to detect the data DATA that is stored in the memory cell array 20.

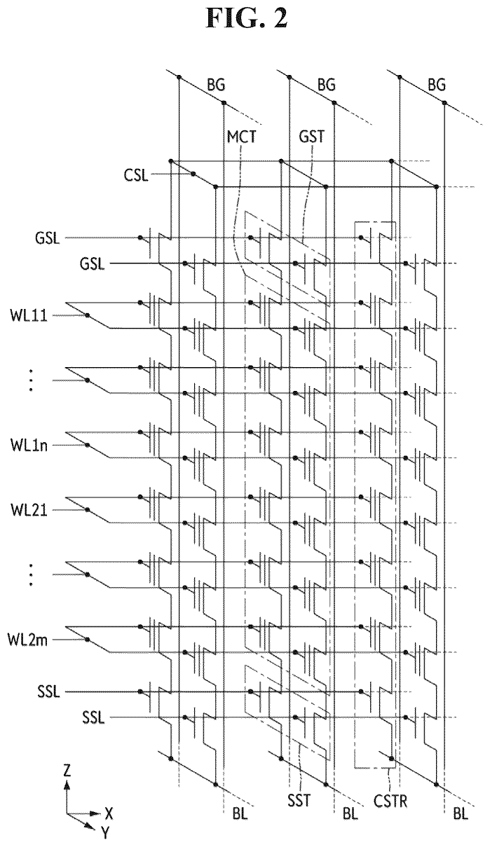

FIG. 2 is an example circuit diagram for illustrating a semiconductor memory device according to embodiments of the present inventive concept.

Referring to FIG. 2, the memory cell array (e.g., 20 in FIG. 1) of the semiconductor memory device according to embodiments of the present inventive concept includes a common source line CSL, a plurality of bit-lines BL, a plurality of cell strings CSTR and a plurality of back gate electrodes BG.

The plurality of bit-lines BL may be two-dimensionally arranged in a plane that is defined by the first direction X and the second direction Y. For example, the bit-lines BL may be arranged and spaced apart from each other in the first direction X and extend in the second direction Y that intersects the first direction X. The plurality of cell strings CSTR may be connected in parallel to each of the bit-lines BL. The cell strings CSTR may be commonly connected to the common source line CSL. That is, the plurality of cell strings CSTR may be disposed between the bit-lines BL and the common source line CSL.

Each of the cell strings CSTR may include a ground select transistor GST connected to the common source line CSL, a string select transistor SST connected to the bit-line BL, and a plurality of memory cell transistors MCT disposed between the ground select transistor GST and the string select transistor SST. Each of the memory cell transistors MCT may include a data storage element. The ground select transistor GST, the string select transistor SST and the memory cell transistors MCT may be connected in series to each other.

The common source line CSL may be commonly connected to sources of the ground select transistors GST. Further, a ground select line GSL, a plurality of word-lines WL11 to WL1n and WL21 to WL2n, and a string select line SSL may be disposed between the common source line CSL and the bit-line BL. The ground select line GSL may act as a gate electrode of the ground select transistor GST. The word-lines WL11 to WL1n and WL21 to WL2n may be respectively used as gate electrodes of the memory cell transistors MCT. The string select line SSL may act as a gate electrode of the string select transistor SST.

The back gate electrodes BG may extend in parallel to the plurality of cell strings CSTR. For example, the back gate electrodes BG may extend in a third direction Z that intersects the first direction X and the second direction Y. In embodiments of the present inventive concept, a plurality of back gate electrodes BG arranged in a line along the second direction Y may be connected to each other.

The back gate electrodes BG may be used as the back gate electrodes of the memory cell transistors MCT. The voltage applied to the word-lines WL11 to WL1n, and WL21 to WL2m and the voltage applied to the back gate electrode BG may be different from each other.

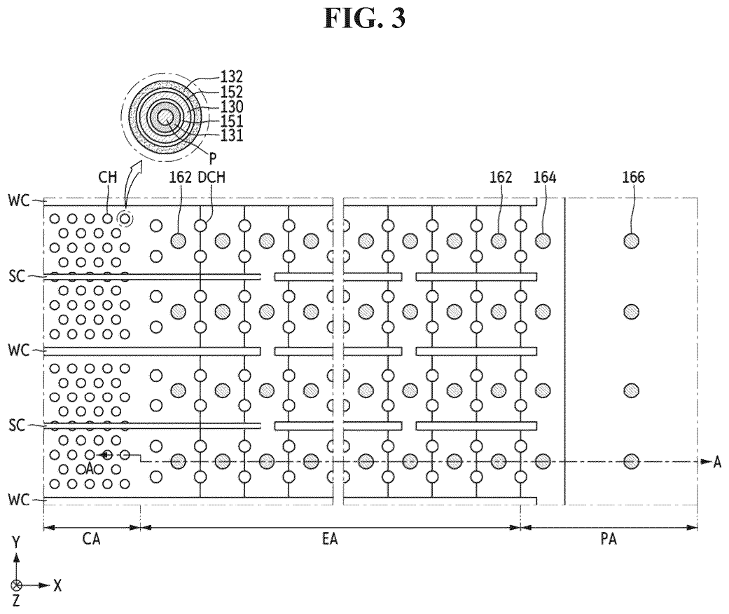

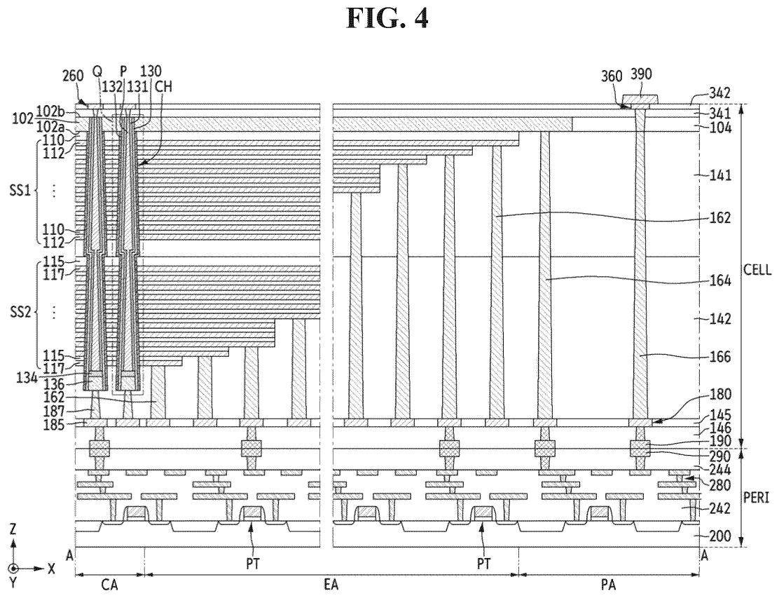

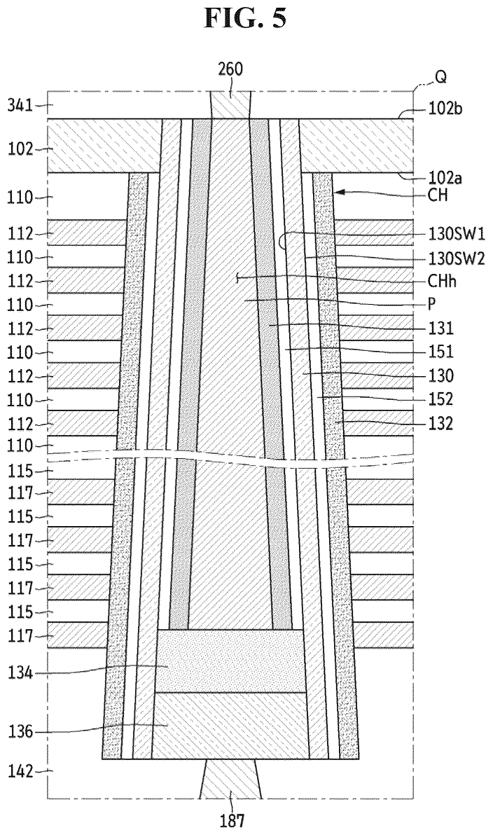

FIG. 3 is a layout diagram for illustrating a semiconductor memory device according to embodiments of the present inventive concept. FIG. 4 is a cross-sectional view cut along A-A in FIG. 3. FIG. 5 is an enlarged view illustrating a Q area of FIG. 4.

Referring to FIG. 3 to FIG. 5, a semiconductor memory device according to embodiments of the present inventive concept includes a memory cell structure CELL, a peripheral circuit structure PERI, and a conductive pad 390.

The memory cell structure CELL may include a cell array area CA, an extension area EA, and a peripheral area PA.

A memory cell array (for example, 20 in FIG. 1) including a plurality of memory cells may be formed in the cell array area CA. For example, a source layer 120, a channel structure CH, the gate electrodes 112 and 117, a bit-line BL, which will be described later may be disposed in the cell array area CA.

The extension area EA may be disposed around the cell array area CA. For example, the extension area EA may be adjacent to the cell array area CA in the first direction X. In the extension area EA, the gate electrodes 112 and 117, which will be described later, may be stacked in a stepped manner.

The peripheral area PA may be a peripheral area at least partially surrounding the cell array area CA and the extension area EA. For example, the peripheral area PA may be adjacent to the cell array area CA and/or the extension area EA in the first direction X and/or the second direction Y. The conductive pad 390, which will be described later, may be disposed in the peripheral area PA.

The memory cell structure CELL may include a source layer 102, an insulating substrate 104, a stack structure SS1 and SS2, a channel structure CH, a cutting pattern WC, a gate contact 162, a source contact 164, a through-via 166, and a cell wiring structure 180.

The source layer 102 may include a conductive material, for example, polysilicon doped with impurities, metal, or metal silicide. Embodiments of the present inventive concept are not limited thereto. For example, the source layer 102 may include polysilicon (poly-Si) doped with N-type impurities, such as phosphorus (P) or arsenic (As).

The source layer 102 may be provided as a common source line (for example, CSL in FIG. 2) of the semiconductor memory device according to embodiments of the present inventive concept.

The source layer 102 may include a first surface 102a and a second surface 102b, which are opposite to each other. In the description set forth below as an example, the first surface 102a may also be referred to as a front surface of the source layer 102, and the second surface 102b may also be referred to as a back surface of the source layer 102.

The insulating substrate 104 may be formed around the source layer 102. The insulating substrate 104 may constitute an insulating area around the source layer 102 and across the cell array area CA and/or the peripheral area PA. The insulating substrate 104 may include, but is not limited to, at least one of silicon oxide, silicon nitride, silicon oxynitride, and/or silicon carbide.

The stack structure SS1 and SS2 may be formed on the first surface 102a of the source layer 102. The stack structure SS1 and SS2 may include a plurality of gate electrodes 112 and 117 and a plurality of mold insulating films 110 and 115 stacked on the source layer 102. Each of the gate electrodes 112 and 117 and each of the mold insulating films 110 and 115 may have a layered structure extending in a horizontal direction (such as the first direction X and the second direction Y). The gate electrodes 112 and 117 may be sequentially stacked while being spaced apart from each other via each of the mold insulating films 110 and 115.

The gate electrodes 112 and 117 of the extension area EA may be stacked in a stepped manner on the source layer 102. For example, in the extension area EA, a length by which each of the gate electrodes 112 and 117 extends in the first direction X may decrease as each of the gate electrodes 112 and 117 are stacked away from the source layer 102.

In embodiments of the present inventive concept, the stack structure SS1 and SS2 may include a plurality of stacks (for example, the first stack SS1 and the second stack SS2) sequentially stacked on the source layer 102. It is shown only that the number of stacks stacked on the source layer 102 is two. However, this is only an example, and, in another example, the number of stacks stacked on the source layer 102 may be three or more.

The first stack SS1 may include the first mold insulating films 110 and the first gate electrodes 112 that are alternately stacked on top of each other while being disposed on the source layer 102. In embodiments of the present inventive concept, the first gate electrodes 112 may include at least one ground select line (e.g., GSL in FIG. 2), and a plurality of first word-lines (e.g., WL11 to WL1n in FIG. 2) which are sequentially stacked on the source layer 102. The number and shape of the first mold insulating films 110 and the first gate electrodes 112 are only examples and are not limited to those shown.

A first interlayer insulating film 141 covering the first stack SS1 may be formed on the source layer 102 and the insulating substrate 104. The first interlayer insulating film 141 may include, but is not limited to, at least one of, for example, silicon oxide, silicon oxynitride, and a low-k material with a lower dielectric constant than that of silicon oxide.

The second stack SS2 may include the second mold insulating films 115 and the second gate electrodes 117 which are alternately stacked on top of each other while being disposed on the first stack SS1. In embodiments of the present inventive concept, the second gate electrodes 117 may include a plurality of second word-lines (e.g., WL21 to WL2m in FIG. 2) and at least one string select line (e.g., SSL in FIG. 2) which are sequentially stacked on the first stack SS1. The number and shape of the second mold insulating films 115 and the second gate electrodes 117 are only examples and are not limited to those shown.

A second interlayer insulating film 142 covering the second stack SS2 may be formed on the first interlayer insulating film 141. The second interlayer insulating film 142 may include, but is not limited to, at least one of, for example, silicon oxide, silicon oxynitride, and a low-k material with a lower dielectric constant than that of silicon oxide.

Each of the gate electrodes 112 and 117 may include a conductive material, for example, a metal such as tungsten (W), molybdenum (Mo), ruthenium (Ru), cobalt (Co), or nickel (Ni), or a semiconductor material such as silicon. However, embodiments of the present inventive concept are not limited thereto. For example, each of the gate electrodes 112 and 117 may include at least one of tungsten (W), molybdenum (Mo), and/or ruthenium (Ru). In an example, each of the gate electrodes 112 and 117 may include polysilicon.

Each of the mold insulating films 110 and 115 may include at least one of, for example, silicon oxide, silicon nitride, and silicon oxynitride. However, embodiments of the present inventive concept are not limited thereto. For example, each of the mold insulating films 110 and 115 may include a silicon oxide film.

The channel structure CH may be disposed in the cell array area CA. The channel structure CH may be formed on the source layer 102. The channel structure CH may extend in the third direction Z which intersects the first direction X and the second direction Y and may extend through the stack structure SS1 and SS2. For example, the channel structure CH may be a pillar-shaped structure (for example, a cylindrical structure) extending in the third direction Z. This channel structure CH may intersect with the plurality of gate electrodes 112 and 117.

The channel structure CH may be electrically connected to the source layer 102. For example, as shown, an upper surface of the channel structure CH may be substantially coplanar with the second surface 102b of the source layer 102. A top portion of the channel structure CH may extend into in the source layer 102. For example, as shown, the top portion of the channel structure CH may be surrounded with the source layer 102.

In embodiments of the present inventive concept, a plurality of the channel structures CH may be arranged in a zigzag shape or an alternating arrangement in a plan view. For example, as shown in FIG. 3, the channel structures CH may be arranged in a staggered manner in each of the first direction X and the second direction Y. These channel structures CH may further increase an integration density of the semiconductor memory device. The number and the arrangement of the channel structures CH are only examples, and are not limited to what are shown.

In embodiments of the present inventive concept, each of the channel structure CH may have a stepped portion between the first stack SS1 and the second stack SS2. For example, as shown in FIG. 4, a side surface of each channel structure CH may have a bent portion at a boundary between the first interlayer insulating film 141 and the second stack SS2.

Each channel structure CH may include a conductive pillar P, a channel film 130, a first data storage film 131, a first interfacial film 151, a second interfacial film 152, a second data storage film 132, a channel pad 136, and a capping insulating film 134.

The conductive pillar P may be disposed in the channel hole CHh of the channel structure CH. For example, the conductive pillar P may be disposed at a center of a channel hole CHh of the channel structure CH. The conductive pillar P may extend in the third direction Z. The conductive pillar P may correspond to the back gate electrode BG described above with reference to FIG. 2. An upper surface of the conductive pillar P may be substantially coplanar with the second surface 102b of the source layer 102. For example, the upper surface of the conductive pillar P and the second surface 102b of the source layer 102 may constitute or may be disposed in the same plane. As used herein, “the same” means not only being completely identical with each other but also including a minute difference that may occur due to a margin in the process or manufacturing, etc. The conductive pillar P may extend through the source layer 102.

The conductive pillar P may include a conductive material, for example, a metal such as tungsten (W), molybdenum (Mo), ruthenium (Ru), cobalt (Co), or nickel (Ni), or a semiconductor material such as silicon. Embodiments of the present inventive concept are not limited thereto. For example, the conductive pillar P may include at least one of tungsten (W), molybdenum (Mo), and ruthenium (Ru). In another example, the conductive pillar P may include polysilicon.

The channel film 130 may be interposed between the conductive pillar P and the plurality of gate electrodes 112 and 117. The channel film 130 may be disposed on a side surface of the conductive pillar P and surround the conductive pillar P. The channel film 130 may extend in the third direction Z and intersect the plurality of gate electrodes 112 and 117. The channel film 130 may include, but is not limited to, a semiconductor material such as single crystal silicon, polycrystalline silicon, organic semiconductor materials, and carbon nanostructures.

The channel film 130 may be disposed on the source layer 102. For example, the channel film 130 may be in contact with the source layer 102. In embodiments of the present inventive concept, the channel film 130 may extend through the first surface 102a of the source layer 102. For example, an upper surface of the channel film 130 may be at a higher vertical level than that of the first surface 102a of the source layer 102. In embodiments of the present inventive concept, the upper surface of the channel film 130 may be substantially coplanar with the second surface 102b of the source layer 102. This channel film 130 may reduce contact resistance by increasing a contact area thereof with the source layer 102.

The first interfacial film 151 may be interposed between the conductive pillar P and the channel film 130. For example, the first interfacial film 151 may conformally extend along a profile of an inner side surface of the channel film 130. In embodiments of the present inventive concept, the first interfacial film 151 may extend in the third direction Z and extend through the first surface 102a of the source layer 102. In embodiments of the present inventive concept, the first interfacial film 151 may be substantially coplanar with the second surface 102b of the source layer 102.

The first interfacial film 151 may include at least one of, for example, silicon oxide, silicon nitride, silicon oxynitride, a high dielectric constant material (such as aluminum oxide (Al₂O₃) or hafnium oxide (HfO₂)) with a dielectric constant that is higher than that of silicon oxide, and combinations thereof. For example, the first interfacial film 151 may include silicon oxide. In embodiments of the present inventive concept, when the channel film 130 includes a semiconductor material, the first interfacial film 151 may include an oxide of the semiconductor material. For example, the first interfacial film 151 may include a native oxide film of the semiconductor film included in the channel film 130.

The first data storage film 131 may be interposed between the conductive pillar P and the first interfacial film 151. The first data storage film 131 may be disposed on a side surface of the conductive pillar P. For example, the first data storage film 131 may extend conformally along a profile of an outer side surface of the conductive pillar P.

The first data storage film 131 may be disposed on one side surface 130SW1 of the channel film 130. The first data storage film 131 may surround the conductive pillar P while being disposed on the side surface 130SW1 of the channel film 130.

In embodiments of the present inventive concept, the first data storage film 131 may extend through the first surface 102a of the source layer 102. In embodiments of the present inventive concept, the upper surface of the first data storage film 131 may be substantially coplanar with the second surface 102b of the source layer 102.

In embodiments of the present inventive concept, the first data storage film 131 may include a ferroelectric film. The ferroelectric film may include at least one of, for example, hafnium oxide, zirconium oxide, yttrium-doped zirconium oxide, yttrium-doped hafnium oxide, magnesium-doped zirconium oxide, magnesium-doped hafnium oxide, silicon-doped hafnium oxide, silicon-doped zirconium oxide, barium-doped titanium oxide, and combinations thereof. Embodiments of the present inventive concept are not limited thereto.

In embodiments of the present inventive concept, the first data storage film 131 may include an electrolyte film. For example, the electrolyte film may include an oxide-based electrolyte material. In another example, the electrolyte film may include non-stoichiometric hafnium oxide.

The second interfacial film 152 may be interposed between the plurality of gate electrodes 112 and 117 and the channel film 130. The second interfacial film 152 may be disposed on the other side surface 130SW2 opposite to the one side surface 130SW1 of the channel film 130 and extend in the third direction Z. For example, the second interfacial film 152 may extend conformally along a profile of the outer side surface of the channel film 130.

In embodiments of the present inventive concept, an upper surface of the second interfacial film 152 may contact the first surface 102a of the source layer 102. In embodiments of the present inventive concept, the upper surface of the second interfacial film 152 may be substantially coplanar with the first surface 102a of the source layer 102.

The second interfacial film 152 includes at least one of, for example, silicon oxide, silicon nitride, silicon oxynitride, a high dielectric constant material (such as aluminum oxide (Al₂O₃) or hafnium oxide (HfO₂)) with a dielectric constant higher than that of silicon oxide, and combinations thereof. For example, the second interfacial film 152 may include silicon oxide. In embodiments of the present inventive concept, when the channel film 130 includes a semiconductor material, the second interfacial film 152 may include an oxide of the semiconductor material. For example, the second interfacial film 152 may include a native oxide film of the semiconductor film included in the channel film 130.

The second data storage film 132 may be interposed between the plurality of gate electrodes 112 and 117 and the second interfacial film 152. The second data storage film 132 may be disposed on the other side surface 130SW2 of the channel film 130 and extend in the third direction Z. For example, the second data storage film 132 may conformally extend along a profile of the outer side surface of the second interfacial film 152. The second data storage film 132 may surround the second interfacial film 152 while being disposed on the other side surface 130SW2 of the channel film 130.

The second data storage film 132 may be disposed on the source layer 102. For example, an upper surface of the second data storage film 132 may be in contact with the first surface 102a of the source layer 102. The upper surface of the second data storage film 132 may be substantially coplanar with the first surface 102a of the source layer 102.

In embodiments of the present inventive concept, the second data storage film 132 may be in contact with a plurality of gate electrodes 112 and 117. In a plan view, the second data storage film 132 may be surrounded with the plurality of gate electrodes 112 and 117.

The second data storage film 132 may include a ferroelectric film. The ferroelectric film may include at least one of, for example, hafnium oxide, zirconium oxide, yttrium-doped zirconium oxide, yttrium-doped hafnium oxide, magnesium-doped zirconium oxide, magnesium-doped hafnium oxide, silicon-doped hafnium oxide, silicon-doped zirconium oxide, barium-doped titanium oxide, and combinations thereof. Embodiments of the present inventive concept are not limited thereto.

The channel pad 136 may be in contact with one end of the channel film 130. The channel pad 136 may be disposed on the conductive pillar P. The channel pad 136 may be disposed on one side surface 130SW1 of the channel film 130. The channel pad 136 may include, but is not limited to, a conductive material such as polysilicon doped with impurities, metal, or metal silicide.

The capping insulating film 134 may be interposed between the conductive pillar P and the channel pad 136. The capping insulating film 134 may be connected to the conductive pillar P, the first data storage film 131, and the first interfacial film 151. In embodiments of the present inventive concept, the capping insulating film 134 may be disposed on one side surface 130SW1 of the channel film 130. For example, the capping insulating film 134 may be surrounded by the conductive pillar P, the first data storage film 131, the first interfacial film 151, the channel film 130, and the channel pad 136.

The capping insulating film 134 may include an insulating material, for example, silicon oxide. Embodiments of the present inventive concept are not limited thereto.

The cutting pattern WC may extend across the cell array area CA and the extension area EA. The cutting pattern WC extends in an elongated manner in the first direction X and may cut the stack structure SS1 and SS2. Furthermore, a plurality of cutting patterns WC may be spaced apart from each other and may be arranged along the second direction Y. The stack structure SS1 and SS2 may be cut by the plurality of cutting patterns WC into a plurality of memory cell blocks (e.g., BLK1 to BLKn in FIG. 1). For example, two adjacent cutting patterns WC may define one memory cell block therebetween. A plurality of channel structures CH may be disposed within each memory cell block that is defined by the cutting patterns WC.

In embodiments of the present inventive concept, the cutting pattern WC may include an insulating material, for example, at least one of silicon oxide, silicon nitride, and silicon oxynitride. However, embodiments of the present inventive concept are not limited thereto. In one example, the cutting pattern WC may include a silicon oxide film.

In embodiments of the present inventive concept, an isolation pattern SC may be formed within the second stack structure SS2. The isolation pattern SC may extend in the first direction X to cut the string select line (SSL in FIG. 2; for example, the lowest gate electrode among the second gate electrodes 117) of the second stack structure SS2. Each memory cell block defined by the cutting patterns WC may be divided by the isolation pattern SC into a plurality of string areas. In one example, the isolation pattern SC may define two string areas within one memory cell block. The isolation pattern SC may include an insulating material, for example, at least one of silicon oxide, silicon nitride, and silicon oxynitride. However, embodiments of the present inventive concept are not limited thereto.

The gate contact 162 may be disposed within the extension area EA. The gate contact 162 may be electrically connected to the gate electrodes 112 and 117. Each of a plurality of gate contacts 162 may extend in the third direction Z through the first interlayer insulating film 141 and the second interlayer insulating film 142 so as to contact a corresponding one of the gate electrodes 112 and 117. In embodiments of the present inventive concept, a width of the gate contact 162 may decrease as the gate contact extends toward the corresponding one of the gate electrodes 112 and 117.

The source contact 164 may be disposed within the peripheral area PA. The source contact 164 may be electrically connected to the source layer 102. For example, the source contact 164 may extend in the third direction Z through the first interlayer insulating film 141 and the second interlayer insulating film 142 so as to be in contact with a portion of the source layer 102 that is not covered with the stack structure SS1 and SS2. In embodiments of the present inventive concept, a width of the source contact 164 may decrease as the source contact 164 extends toward the source layer 102.

The through-via 166 may be disposed within the peripheral area PA. The through-via 166 may overlap with the insulating substrate 104 in the third direction Z. For example, the through-via 166 may extend in the third direction Z through the first interlayer insulating film 141 and the second interlayer insulating film 142 so as to be in contact with the insulating substrate 104. In embodiments of the inventive concept, a width of the through-via 166 may decrease as the through-via extends toward the insulating substrate 104. In embodiments of the present inventive concept, an upper surface of the through-via 166 may be substantially coplanar with a lower surface of the insulating substrate 104 or may be at a higher vertical level than that of the lower surface of the insulating substrate 104.

The cell wiring structure 180 may be disposed on the second interlayer insulating film 142. The cell wiring structure 180 may be electrically connected to the source layer 102, the gate electrodes 112 and 117, and/or the channel structure CH. For example, the first interlayer insulating film 145 may be disposed on the second interlayer insulating film 142. The cell wiring structure 180 may be formed within a first inter-wiring insulating film 145 and may be connected to the source layer 102, the gate electrodes 112 and 117, and/or the channel structure CH. The number of layers and the arrangement of the cell wiring structure 180 are only examples and are not limited to what are shown.

The cell wiring structure 180 may include, but is not limited to, at least one of a conductive material such as aluminum (Al), copper Cu, tungsten (W), molybdenum (Mo), cobalt (Co), ruthenium (Ru), and alloys thereof.

In embodiments of the present inventive concept, the cell wiring structure 180 may include a conductive line 185 disposed within the cell array area CA. The conductive line 185 may extend in an elongated manner in the second direction Y. Furthermore, each of a plurality of conductive lines 185 may extend in the second direction Y, and the plurality of conductive lines 185 may be spaced apart from each other and arranged along the first direction X.

The conductive line 185 may be electrically connected to the plurality of the channel structures CH arranged along the second direction Y. For example, a channel contact 187 may extend in the third direction Z and between the conductive line 185 and the channel structure CH so as to connect the channel pad 136 and the conductive line 185 to each other. The conductive line 185 may be connected to one end of the channel film 130 via the channel contact 187 and the channel pad 136. This conductive line 185 may be provided as the bit-line (for example, BL in FIG. 2) of the semiconductor memory device according to embodiments of the present inventive concept. In embodiments of the present inventive concept, a width of the channel contact 187 may decrease as the channel contact 187 extends toward the channel structure CH.

In embodiments of the present inventive concept, the semiconductor memory device may include a first contact pattern 260, which is disposed on the channel structure CH, and a second contact pattern 360, which is disposed on the through-via 166.

The first contact pattern 260 may be electrically connected to the conductive pillar P. The second contact pattern 360 may be electrically connected to the through-via 166. Each of the first contact pattern 260 and the second contact pattern 360 may include a conductive material.

A first upper insulating film 341 and a second upper insulating film 342 may be disposed on the source layer 102 and the insulating substrate 104. The first upper insulating film 341 and the second upper insulating film 342 may cover the first contact pattern 260 and the second contact pattern 360, respectively. Each of the first upper insulating film 341 and the second upper insulating film 342 may include an insulating material.

The peripheral circuit structure PERI may include a peripheral circuit substrate 200, a peripheral circuit element PT, and a peripheral circuit wiring structure 280.

The peripheral circuit substrate 200 may include, for example, a semiconductor substrate such as a silicon substrate, a germanium substrate, or a silicon-germanium substrate. In addition, the peripheral circuit substrate 200 may include, for example, a silicon-on-insulator (SOI) substrate or a germanium-on-insulator (GOI) substrate, etc.

The peripheral circuit element PT may be formed on the peripheral circuit substrate 200. The peripheral circuit element PT may constitute a peripheral circuit (e.g., 30 in FIG. 1) that controls an operation of the semiconductor memory device. For example, the peripheral circuit element PT may include a control logic (e.g., 37 in FIG. 1), a row decoder (e.g., 33 in FIG. 1), and a page buffer (e.g., 35 in FIG. 1). In following description, a surface of the peripheral circuit substrate 200 on which the peripheral circuit element PT is disposed may be referred to as a front surface (front side) of the peripheral circuit substrate 200. In addition, a surface of the peripheral circuit substrate 200 opposite to the front surface of the peripheral circuit substrate 200 may be referred to as a rear surface (back side) of the peripheral circuit substrate 200.

The peripheral circuit element PT may include, for example, a transistor. However, the present inventive concept is not limited thereto. For example, the peripheral circuit element PT may include not only various active elements such as transistors, but also various passive elements such as capacitors, resistors, and inductors.

The peripheral circuit wiring structure 280 may be disposed on the peripheral circuit element PT. For example, a second inter-wiring insulating film 242 may be disposed on the front surface of the peripheral circuit substrate 200. The peripheral circuit wiring structure 280 may be disposed within the second inter-wiring insulating film 242. The peripheral circuit wiring structure 280 may be electrically connected to the peripheral circuit element PT. The number of layers and the arrangement of the peripheral circuit wiring structure 280 as illustrated are only examples. The present inventive concept is not limited thereto.

In embodiments of the present inventive concept, the memory cell structure CELL may be stacked on the peripheral circuit structure PERI. For example, the memory cell structure CELL may be stacked on an upper surface of the second inter-wiring insulating film 242.

In embodiments of the present inventive concept, the first surface 102a of the source layer 102 may face the peripheral circuit structure PERI. For example, the stack structure SS1 and SS2 may be interposed between the source layer 102 and the peripheral circuit structure PERI.

The semiconductor memory device according to embodiments of the present inventive concept may have a C2C (chip to chip) structure. The C2C structure may be manufactured by forming an upper chip including the memory cell structure CELL on a first wafer, and then forming a lower chip including the peripheral circuit structure PERI on a second wafer different from the first wafer, and then connecting the upper chip and the lower chip to each other in a bonding scheme.

In one example, the bonding scheme may refer to a scheme in which a first bonding metal 190 (and/or a first bonding insulating film 146) as the uppermost metal layer of the upper chip and a second bonding metal 290 (and/or a second bonding insulating film 244) as the uppermost metal layer of the lower chip are electrically connected to each other. For example, when each of the first bonding metal 190 and the second bonding metal 290 are made of copper (Cu), the bonding scheme may be a Cu—Cu bonding scheme. However, this is only an example. In another example, each of the first bonding metal 190 and the second bonding metal 290 may be made of various other metals such as aluminum (Al) or tungsten (W).

As the first bonding metal 190 and the second bonding metal 290 are bonded to each other, the first wiring structure 180 may be electrically connected to the peripheral circuit wiring structure 280. Thus, a plurality of memory cells formed in the cell array area CA may be electrically connected to the peripheral circuit element PT.

The conductive pad 390 may be disposed on the second surface 102b of the source layer 102. For example, the first upper insulating film 341 and the second upper insulating film 342 covering the second surface 102b of the source layer 102 and the insulating substrate 104 may be disposed below the conductive pad 390. The conductive pad 390 may be disposed on an upper surface of each of the first and second upper insulating films 341 and 342.

In embodiments of the present inventive concept, the conductive pad 390 may be disposed within the peripheral area PA. The conductive pad 390 may be electrically connected to the memory cell structure CELL and/or the peripheral circuit structure PERI. For example, the second contact pattern 360 may extend through the first and second upper insulating films 341 and 342 so as to contact the through-via 166. The conductive pad 390 may be electrically connected to the peripheral circuit structure PERI via the through-via 166.

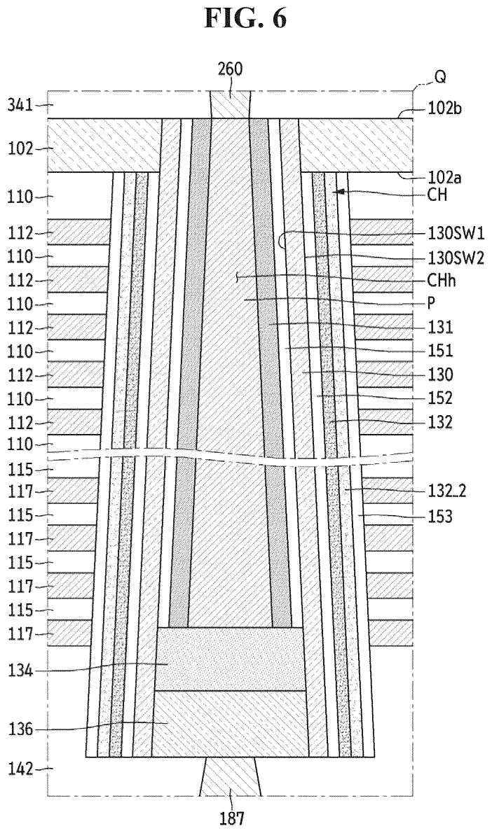

FIG. 6 is a diagram illustrating a semiconductor memory device according to embodiments of the present inventive concept. FIG. 6 is an enlarged view illustrating a Q area of FIG. 4. For convenience of description, contents duplicate with what has been described above with reference to FIG. 3 to FIG. 5 are briefly described or descriptions thereof are omitted.

Referring to FIG. 6, in embodiments of the present inventive concept, the semiconductor memory device may further include a charge storage film 132_2 and a third interfacial film 153 disposed between the second data storage film 132 and the plurality of gate electrodes 112 and 117 and sequentially stacked on the second data storage film 132.

The charge storage film 132_2 may be interposed between the second data storage film 132 and the plurality of gate electrodes 112 and 117. The charge storage film 132_2 may conformally extend along a side surface of the second data storage film 132. The charge storage film 132_2 may be in contact with the source layer 102. For example, the charge storage film 132_2 may be in contact with the first surface 102a of the source layer 102. An upper surface of the charge storage film 132_2 may be substantially coplanar with the first surface 102a of the source layer 102.

For example, the charge storage film 132_2 may include at least one of silicon oxide, silicon nitride, and/or silicon oxynitride. In another example, the charge storage film 132_2 may include at least one of silicon oxide, aluminum oxide, and/or hafnium oxide.

The third interfacial film 153 may be disposed between the charge storage film 132_2 and the plurality of gate electrodes 112 and 117. The third interfacial film 153 may extend conformally along a side surface of the charge storage film 132_2. The third interfacial film 153 may be in contact with the source layer 102. For example, the third interfacial film 153 may be in contact with the first surface 102a of the source layer 102. An upper surface of the third interfacial film 153 may be substantially coplanar with the first surface 102a of the source layer 102. The third interfacial film 153 may include silicon oxide.

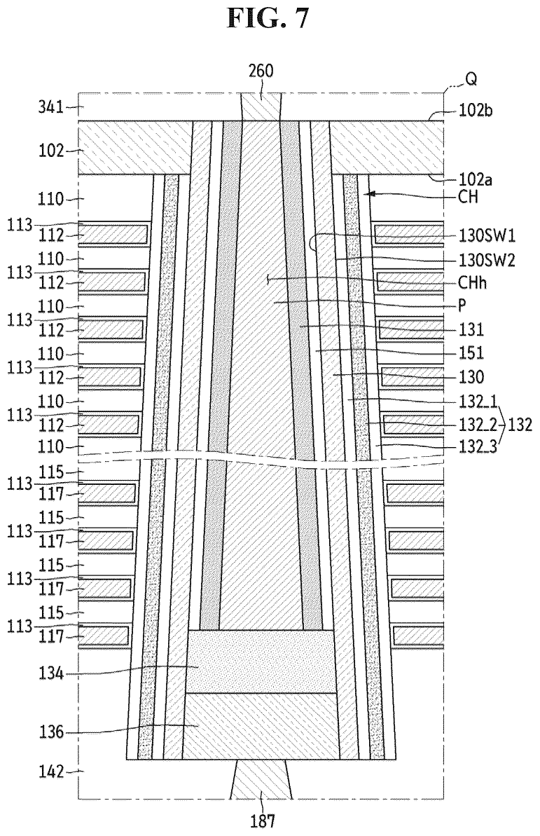

FIG. 7 is a diagram illustrating a semiconductor memory device according to embodiments of the present inventive concept. FIG. 7 is an enlarged view illustrating the Q area of FIG. 4. For convenience of description, contents duplicate with what has been described above with reference to FIG. 3 to FIG. 5 are briefly described or descriptions thereof are omitted.

Referring to FIG. 7, the conductive pillar P may be disposed at the center of the channel hole CHh of the channel structure CH. The channel film 130 may be interposed between the conductive pillar P and the plurality of gate electrodes 112 and 117. The first data storage film 131 and the first interfacial film 151 may be interposed between the conductive pillar P and the channel film 130. The first data storage film 131 may be interposed between the first interfacial film 151 and the conductive pillar P. The first interfacial film 151 may be interposed between the channel film 130 and the first data storage film 131.

The second data storage film 132 may be interposed between the channel film 130 and the plurality of gate electrodes 112 and 117. The second data storage film 132 may include a tunneling insulating film 132_1, a charge storage film 132_2, and a blocking insulating film 132_3, which are sequentially stacked on the channel film 130. The charge storage film 132_2 may be interposed between the plurality of gate electrodes 112 and 117 and the channel film 130. The tunneling insulating film 132_1 may be interposed between the charge storage film 132_2 and the channel film 130. The blocking insulating film 132_3 may be interposed between the charge storage film 132_2 and the plurality of gate electrodes 112 and 117. Each of the tunneling insulating film 132_1, the charge storage film 132_2, and the blocking insulating film 132_3 may extend in the third direction Z so as to contact the source layer 102. For example, each of the tunneling insulating film 132_1, the charge storage film 132_2, and the blocking insulating film 132_3 may extend in the third direction Z so as to contact the first surface 102a of the source layer 102.

The tunneling insulating film 132_1 may include, for example, silicon oxide or a high dielectric constant material (such as aluminum oxide (Al₂O₃) and hafnium oxide (HfO₂)) having a dielectric constant that is higher than that of silicon oxide. For example, the charge storage film 132_2 may include at least one of silicon oxide, silicon nitride, and/or silicon oxynitride. The blocking insulating film 132_3 may include, for example, silicon oxide or a high dielectric constant material (such as aluminum oxide (Al₂O₃) and hafnium oxide (HfO₂)) having a dielectric constant that is higher than that of silicon oxide.

The gate dielectric film 113 may be interposed between each of the gate electrodes 112 and 117 and the blocking insulating film 132_3. The gate dielectric film 113 may extend along an outer surface of each of the gate electrodes 112 and 117. For example, the gate dielectric film 113 may extend conformally along a lower surface, a side surface, and an upper surface of each of the gate electrodes 112 and 117. In embodiments of the present inventive concept, the gate dielectric film 113 may be omitted. In this case, the gate electrodes 112 and 117 may fill an area of the gate dielectric film 113 as shown.

The gate dielectric film 113 may include, for example, at least one of silicon oxide, silicon nitride, silicon oxynitride, and/or a high dielectric constant material having a dielectric constant that is higher than that of silicon oxide. The high dielectric constant material may include at least one of, for example, aluminum oxide, hafnium oxide, lanthanum oxide, tantalum oxide, titanium oxide, lanthanum hafnium oxide, lanthanum aluminum oxide, dysprosium scandium oxide, and combinations thereof. For example, the gate dielectric film 113 may include aluminum oxide.

As the electronic system becomes more sophisticated, various ways to increase a data storage capacity of the semiconductor memory device are being researched. For example, as the device operates in a multi-bit manner greater than or equal to QLC (Quad-Level Cell), expansion of a memory window of the semiconductor memory device may be desirable.

The semiconductor memory device according to embodiments of the present inventive concept may increase the memory window using the channel structure CH including the conductive pillar P and the first data storage film 131. Specifically, as described above, the conductive pillar P may be provided as the back gate electrode (for example, BG in FIG. 2) so as to apply an additional electric field to the first data storage film 131 and/or the channel film 130. Thus, a threshold voltage Vth distribution of the memory cells may be increased and the memory window may be increased. Thus, the semiconductor memory device with increased data storage capacity may be provided.

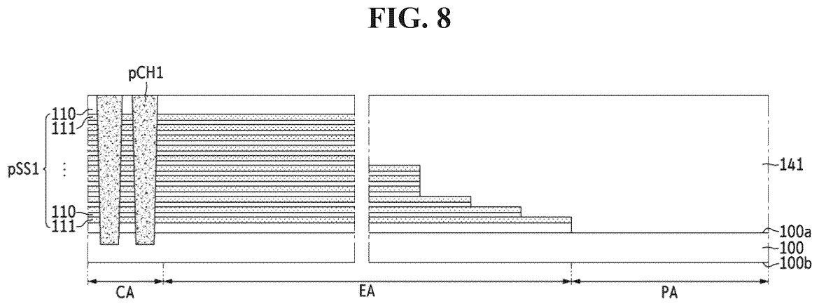

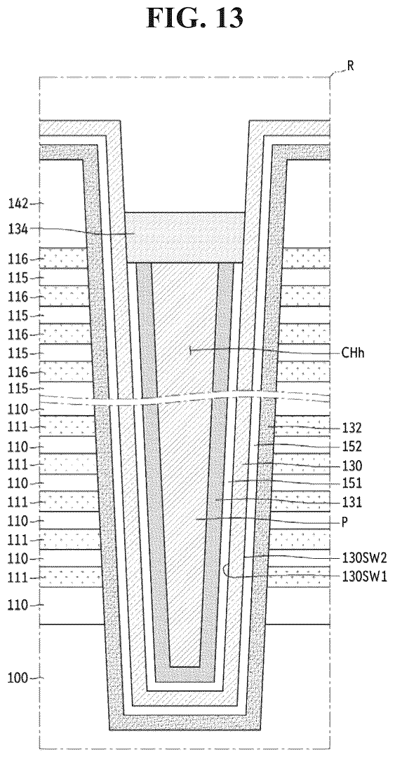

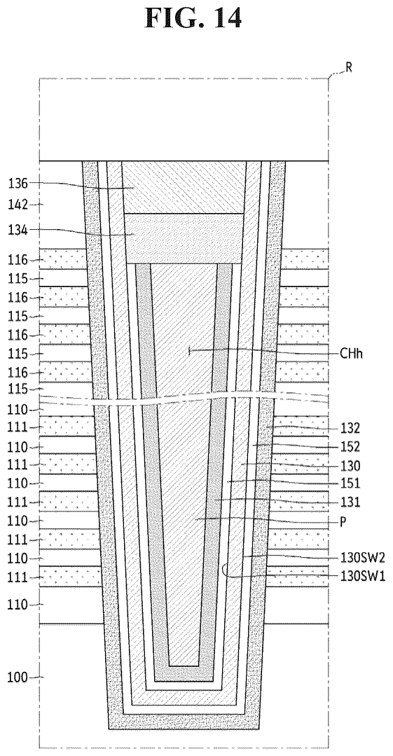

FIG. 8 to FIG. 19 are diagrams of intermediate structures corresponding to intermediate steps of a method for manufacturing a semiconductor memory device in accordance with embodiments of the present inventive concept. For convenience of description, contents that are duplicative of what has already been described above using FIG. 1 to FIG. 7 are briefly described or descriptions thereof are omitted.

Referring to FIG. 8, a first pre-stack pSS1 and a first pre-channel pCH1 are formed on the base substrate 100.

The base substrate 100 may include, for example, a semiconductor substrate such as a silicon substrate, a germanium substrate, or a silicon-germanium substrate. In addition, the base substrate 100 may include a silicon-on-insulator (SOI) substrate or a GOI (Germanium-On-Insulator) substrate, etc.

The base substrate 100 may include a third surface 100a and a fourth surface 100b that are opposite to each other. In following descriptions, as an example, the third surface 100a may also be referred to as a front side or surface of the base substrate 100, and the fourth surface 100b may also be referred to as a back side or surface of the base substrate 100.

The first pre-stack pSS1 may be stacked on the third surface 100a of the base substrate 100. The first pre-stack pSS1 may include a plurality of first mold insulating films 110 and a plurality of first mold sacrificial films 111 that are alternately stacked on top of each other while being disposed on the base substrate 100. The first mold sacrificial films 111 may include a material having an etch selectivity with respect to a material of the first mold insulating films 110. In one example, each of the first mold insulating films 110 may include a silicon oxide film, and each of the first mold sacrificial films 111 may include a silicon nitride film.

The first pre-channel pCH1 may extend in the third direction Z through the first pre-stack pSS1. Furthermore, the first pre-channel pCH1 may be in contact with base substrate 100. For example, the first interlayer insulating film 141 covering the first pre-stack pSS1 may be formed on the base substrate 100. The first pre-channel pCH1 may extend through the first interlayer insulating film 141 and the first pre-stack pSS1, and may contact the base substrate 100.

The first pre-channel pCH1 may include a material having an etch selectivity with respect to a material of each of the first mold insulating films 110 and the first mold sacrificial films 111. In one example, the first pre-channel pCH1 may include polysilicon (poly-Si).

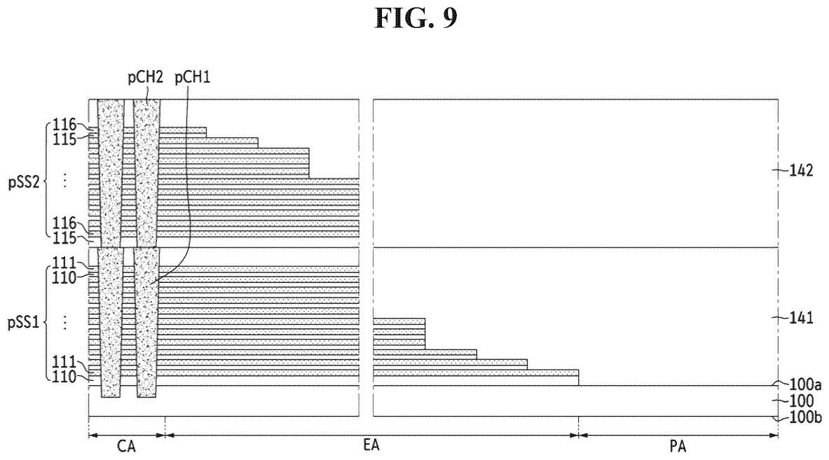

Referring to FIG. 9, a second pre-stack pSS2 and a second pre-channel pCH2 are formed on the first pre-stack pSS1 and the first pre-channel pCH1.

The second pre-stack pSS2 may include a plurality of second mold insulating films 115 and a plurality of second mold sacrificial films 116 that are stacked alternately on top of each other while being disposed on the first pre-stack pSS1. Since forming the second pre-stack pSS2 may be similar to forming the first pre-stack pSS1, detailed description thereof is omitted below.

The second pre-channel pCH2 may extend in the third direction Z and extend through the second pre-stack pSS2. Furthermore, the second pre-channel pCH2 may contact the first pre-channel pCH1. Since a forming of the second pre-channel pCH2 may be similar to the forming of the first pre-channel pCH1, detailed description thereof is omitted below.

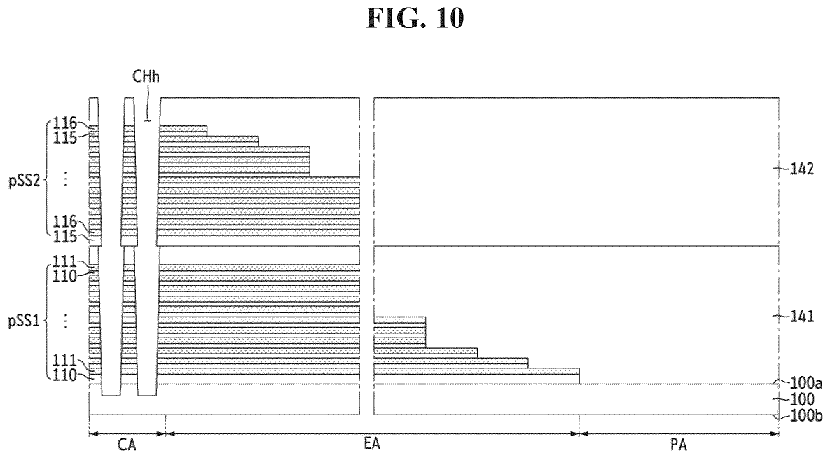

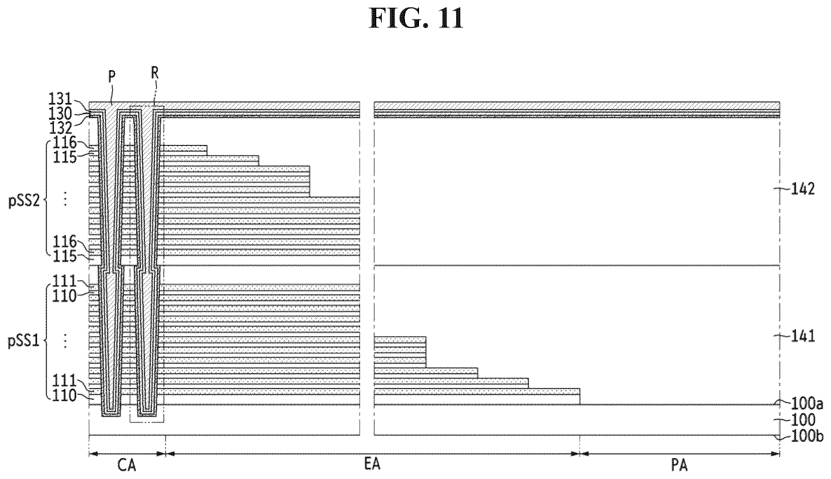

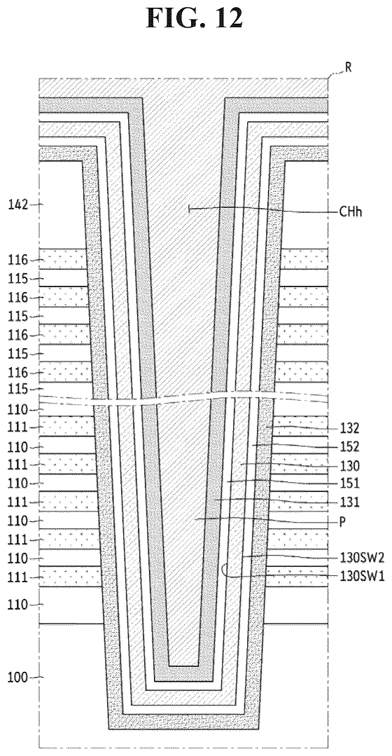

Referring to FIG. 10 to FIG. 17, the channel structure CH is formed, and the plurality of gate electrodes 112 and 117 are formed. FIG. 12 to FIG. 16 are enlarged diagrams of a R area in FIG. 11.

In FIG. 10, the first pre-channel pCH1 and the second pre-channel pCH2 may be selectively removed. The first pre-channel pCH1 and the second pre-channel pCH2 may be removed to form the channel hole CHh.

Referring to FIG. 11 to FIG. 14 and FIG. 17, in embodiments of the present inventive concept, the channel hole CHh may be filled with the second data storage film 132, the second interfacial film 152, the channel film 130, the first interfacial film 151, and the conductive pillar P in this order.

Subsequently, through a wet etching process, a portion of the conductive pillar P, a portion of the first data storage film 131, and a portion of the first interfacial film 151 are removed. Through the wet etching process, the conductive pillar P, the first data storage film 131 and the first interfacial film 151 may be exposed.

Subsequently, the capping insulating film 134 is formed on the conductive pillar P. The capping insulating film 134 may cap the conductive pillar P and the first data storage film 131 and the first interfacial film 151.

Subsequently, the channel pad 136 may be deposited on the capping insulating film 134, and a CMP (Chemical Mechanical Polishing) process may be performed thereon. In the CMP process, an upper surface of the channel pad 136, an upper surface of the channel film 130, the upper surface of the second interfacial film 152, and an upper surface of the second data storage film 132 may be substantially coplanar with each other.

Subsequently, the mold sacrificial films 111 and 116 may be removed. The gate electrodes 112 and 117 may be formed to the areas from which the mold sacrificial layers 111 and 116 have been removed. Thus, a first mold stack SS1 including the plurality of first gate electrodes 112 and a second mold stack SS2 including the plurality of second gate electrodes 117 may be formed.

In embodiments of the present inventive concept, before the gate electrodes 112 and 117 are formed, the gate dielectric film 113 may be formed in an area from which the mold sacrificial films 111 and 116 have been removed. Thus, the gate dielectric film 113 extending along the outer surface of each of the gate electrodes 112 and 117 may be formed.

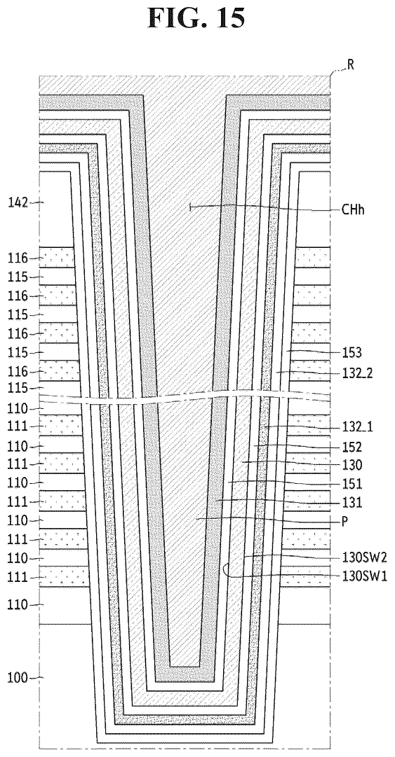

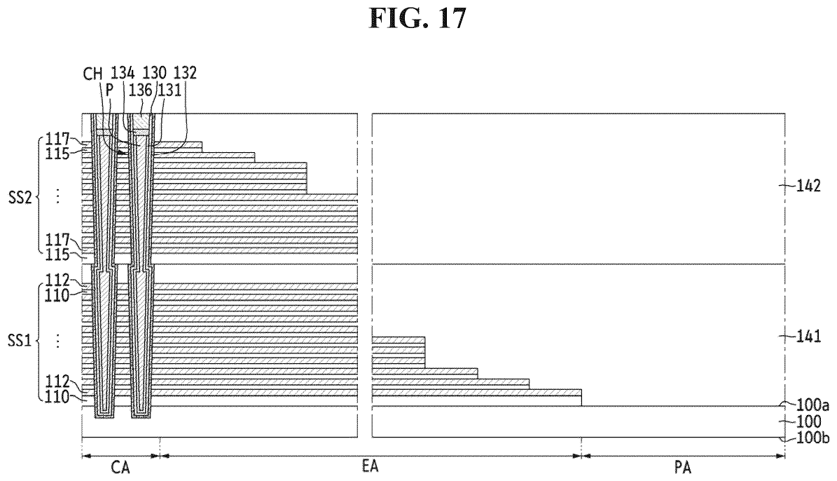

Referring to FIG. 11, FIG. 15 and FIG. 17, in some embodiments of the present inventive concept, the channel hole CHh may be filled with the third interfacial film 153, the charge storage film 132_2, the second data storage film 132, the second interfacial film 152, the channel film 130, the first interfacial film 151 and the conductive pillar P in this order. A subsequent process may be substantially the same as the descriptions provided above with reference to FIG. 11 to FIG. 14. Thus, descriptions thereof are omitted.

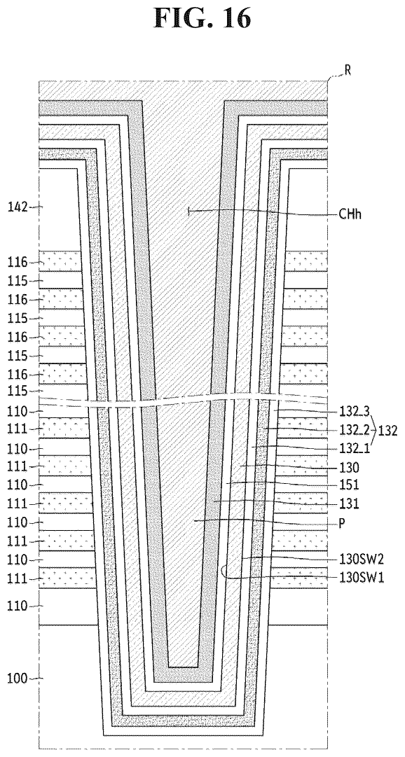

Referring to FIG. 11, FIG. 16, and FIG. 17, in embodiments of the present inventive concept, the channel hole CHh may be filled with the blocking insulating film 132_3, the charge storage film 132_2, the tunnel insulating film 132_1, the channel film 130, the first interfacial film 151, the first data storage film 131 and the conductive pillar P in this order. A subsequent process may be substantially the same as that as described above with reference to FIG. 11 to FIG. 14. Thus, descriptions thereof are omitted or briefly discussed.

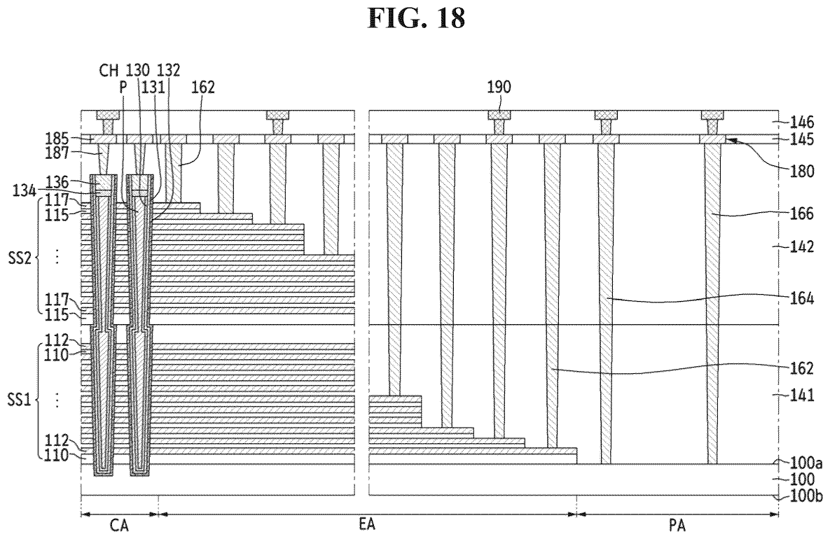

Referring to FIG. 18, the gate contact 162, the through-via 166, the first inter-wiring insulating film 145, the cell wiring structure 180, the first bonding insulating film 146, and the first bonding metal 190 are formed.

The cate contact 162 may be disposed within the extension area EA. The plurality of gate contacts 162 may extend through the interlayer insulating films 141 and 142 and may contact the plurality of gate electrodes 112 and 117 corresponding thereto.

The source contact 164 and the through-via 166 may be disposed within the peripheral area PA. Each of the source contact 164 and the through-via 166 may extend through the interlayer insulating films 141 and 142 and may contact the base substrate 100.

The first interlayer insulating film 145 and the cell wiring structure 180 may be formed on the first interlayer insulating film 141. The cell wiring structure 180 may be electrically connected to the channel structure CH, the gate contact 162, the source contact 164, and/or the through-via 166.

The first bonding insulating film 146 and the first bonding metal 190 may be formed on the first inter-wiring insulating film 145. The first bonding metal 190 may be electrically connected to the cell wiring structure 180.

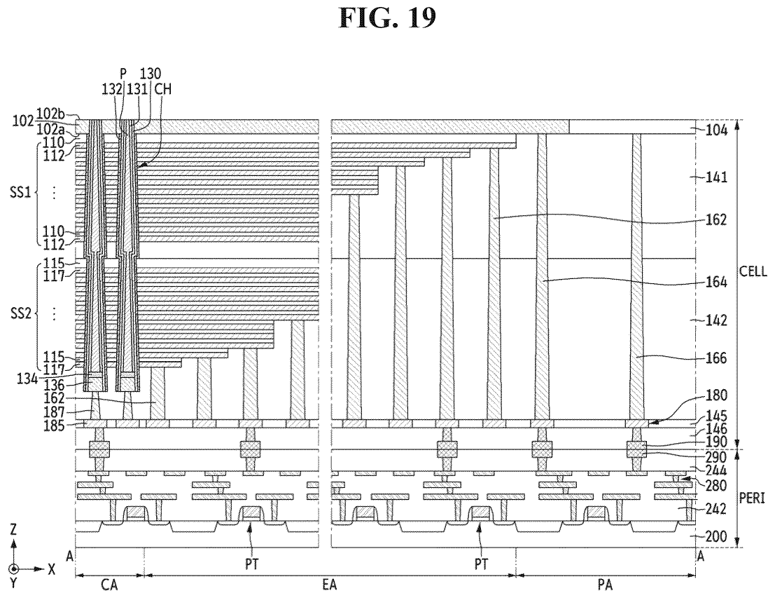

Referring to FIG. 19, the memory cell structure CELL is stacked on the peripheral circuit structure PERI.

In embodiments of the present inventive concept, the memory cell structure CELL may be stacked so that the third surface 100a of the base substrate 100 faces the peripheral circuit structure PERI. For example, the first bonding metal 190, which is formed as the uppermost metal layer of the memory cell structure CELL, and the second bonding metal 290, which is formed as the uppermost metal layer of the peripheral circuit structure PERI, may be bonded to each other. For example, the first bonding insulating film 146 and the second bonding insulating film 244 may be bonded to each other.

Next, the base substrate 100 is removed.

For example, a planarization process or a recess process may be performed on the fourth surface 100b of the base substrate 100. Thus, one end (for example, an upper end) of the channel structure CH may be exposed.

Next, the source layer 102 is formed on the stack structure SS1 and SS2 and the channel structure CH.

The source layer 102 may replace an area from which the base substrate 100 has been removed. Thus, the source layer 102 in contact with the channel film 130 of the channel structure CH may be formed. The source layer 102 may include a conductive material, for example, polysilicon doped with impurities, metal, or metal silicide. Embodiments of the present inventive concept are not limited thereto.

Subsequently, a planarization process may be performed on the source layer 102. Thus, the channel film 130, the first interfacial film 151, the first data storage film 131, and the conductive pillar P may be exposed.

Subsequently, the first contact pattern 260 may be formed on the conductive pillar P. The second contact pattern 360 may be formed on the through-via 166. The first and second upper insulating films 341 and 342 covering the first contact pattern 260 and the second contact pattern 360 may be formed. Subsequently, the conductive pad 390 may be formed on the second contact pattern 360. Thus, the semiconductor memory device as described above with reference to FIG. 4 may be manufactured.

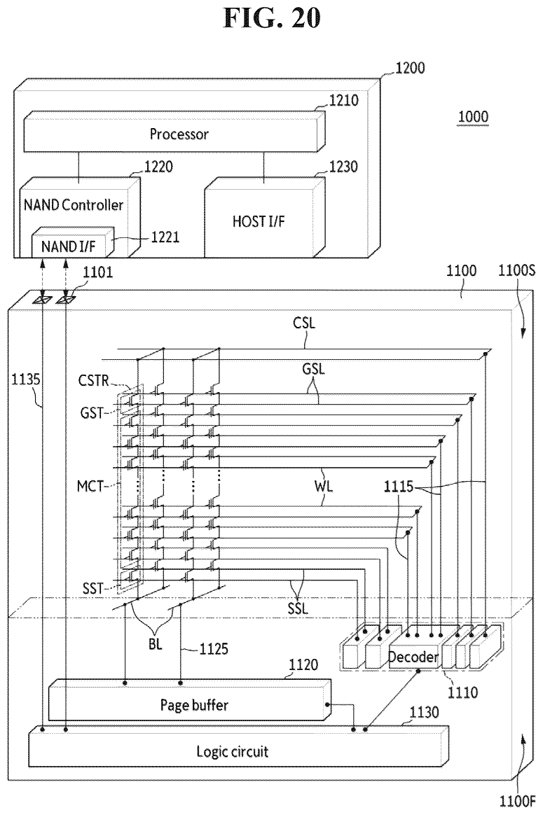

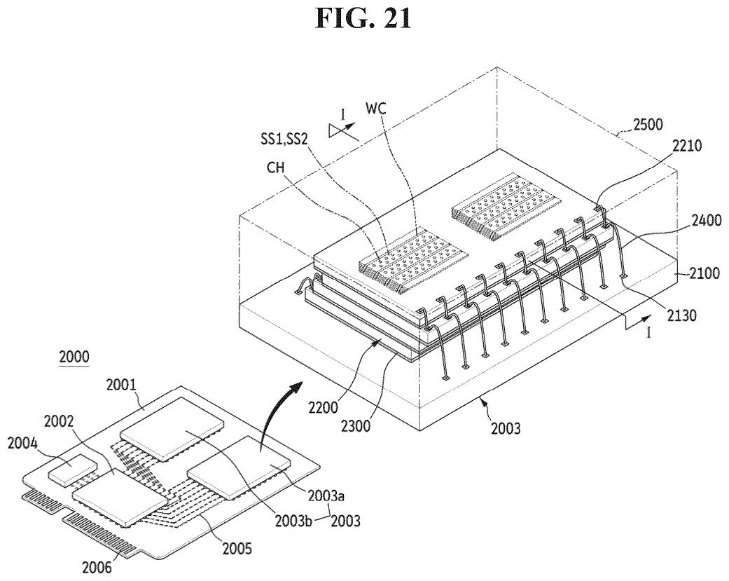

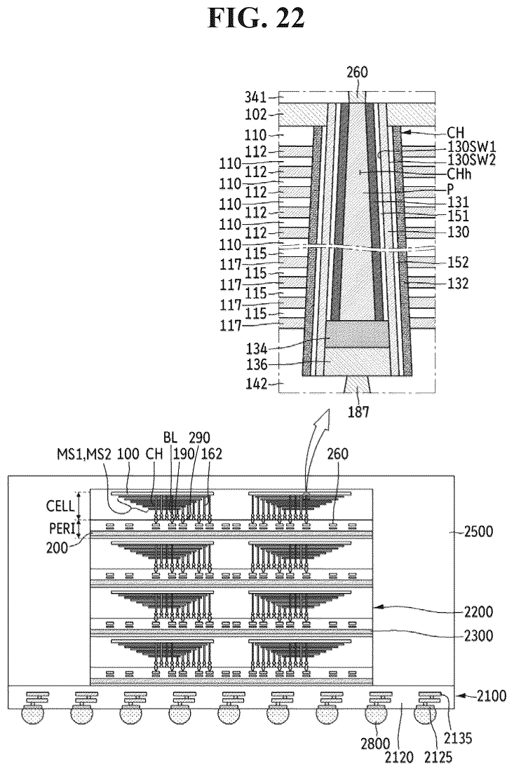

FIG. 20 is an example block diagram illustrating an electronic system according to embodiments of the present inventive concept. FIG. 21 is an example perspective view illustrating an electronic system according to embodiments of the present inventive concept. FIG. 22 is a schematic cross-sectional view cut along I-I in FIG. 21. For convenience of description, contents that are duplicative of what has already been described above with reference to FIG. 1 to FIG. 19 are briefly described or the descriptions thereof are omitted.

Referring to FIG. 20, an electronic system 1000 according to embodiments of the present inventive concept may include a semiconductor memory device 1100 and a controller 1200 electrically connected to the semiconductor memory device 1100. The electronic system 1000 may be a storage device storage device including one or a plurality of semiconductor devices 1100 or an electronic device electronic device including the storage device. For example, the electronic system 1000 may be embodied as a solid state drive device (SSD), a Universal Serial Bus (USB), a computing system, a medical device, or a communication device including one or a plurality of semiconductor memory devices 1100.

For example, the semiconductor memory device 1100 may be embodied as a non-volatile memory device (e.g., a NAND flash memory device). The semiconductor memory device 1100 may be embodied, as for example, at least one of the semiconductor devices as described above with reference to FIGS. 1 to 9. The semiconductor memory device 1100 may include a first structure 1100F and a second structure 1100S that is disposed on the first structure 1100F.

The first structure 1100F may be a peripheral circuit structure including a decoder circuit 1110 (e.g., the row decoder 33 of FIG. 1), a page buffer 1120 (e.g., the page buffer 35 of FIG. 1), and a logic circuit 1130 (e.g., the control logic 37 of FIG. 1). The first structure 1100F may be embodied as, for example, the peripheral circuit structure PERI as described above with reference to FIGS. 1 to 7.

The second structure 1100S may include the common source line CSL, the plurality of bit-lines BL and the plurality of cell strings CSTR as above-described with reference to FIG. 2. The cell strings CSTR may be connected to the decoder circuit 1110 via the plurality of word-lines WL, at least one string select line SSL, and at least one ground select line GSL. Further, the cell strings CSTR may be connected to the page buffer 1120 via the bit-lines BL. The second structure 1100S may be embodied as, for example, the memory cell structure CELL as described above using FIGS. 1 to 7.

In embodiments, the bit-lines BL may be electrically connected to the page buffer 1120 via a second connection wiring 1125.

The semiconductor memory device 1100 may communicate with the controller 1200 via an input/output pad 1101 that is electrically connected to the logic circuit 1130 (e.g., the control logic 37 in FIG. 1). For example, the input/output pad 1101 may correspond to the conductive pad 390 as described above using FIGS. 1 to 7. The input/output pad 1101 may be electrically connected to the logic circuit 1130 via an input/output connection line 1135 extending from the first structure 1100F to the second structure 1100S. The connection line 1135 may be embodied as, for example, the second through-via 166 as described with reference to FIGS. 1 to 7.

The controller 1200 may include a processor 1210, a NAND controller 1220, and a host interface 1230. In embodiments of the present inventive concept, the electronic system 1000 may include a plurality of semiconductor memory devices 1100. In this case, the controller 1200 may control the plurality of semiconductor memory devices 1100. The controller 1200 may control each of the plurality of semiconductor memory devices 1100 such that the voltage may be applied across the plurality of gate electrodes (112 and 117 in FIG. 4) and the conductive pillar (P in FIG. 4) that are included in each of the plurality of semiconductor memory devices 1100. In embodiments of the present inventive concept, the controller 1200 may control each of the plurality of semiconductor memory devices 1100 to apply different voltages to the plurality of gate electrodes 112 and 117 and the conductive pillar P, respectively.

The processor 1210 may control overall operations of the electronic system 1000 including the controller 1200. The processor 1210 may operate based on predefined firmware, and may control the NAND controller 1220 to access the semiconductor memory device 1100. The NAND controller 1220 may include a NAND interface 1221 that processes communication with the semiconductor memory device 1100. Via the NAND interface 1221, a control command for controlling the semiconductor memory device 1100, data to be written to memory cell transistors MCT of the semiconductor memory device 1100, and data to be read from the memory cell transistors MCT of the semiconductor memory device 1100 may be transmitted. The host interface 1230 may provide a communication function between the electronic system 1000 and an external host. Upon receiving a control command from an external host via the host interface 1230, the processor 1210 may control the semiconductor memory device 1100 in response to the control command.

Referring to FIG. 21 and FIG. 22, an electronic system according to embodiments of the present inventive concept may include a main substrate 2001, a main controller 2002 mounted on the main substrate 2001, at least one semiconductor package 2003, and at least one DRAM 2004. The semiconductor package 2003 and the DRAM 2004 may be connected to the main controller 2002 via line patterns 2005 that are formed on the main substrate 2001.

The main substrate 2001 may include a connector 2006 including a plurality of pins that are coupled to an external host. The number and an arrangement of the plurality of pins in the connector 2006 may vary based on a communication interface between the electronic system 2000 and the external host. In embodiments of the present inventive concept, the electronic system 2000 may communicate with the external host using one of interfaces such as USB (Universal Serial Bus), PCI-Express (Peripheral Component Interconnect Express), SATA (Serial Advanced Technology Attachment), M-Phy for UFS (Universal Flash Storage), etc. In embodiments of the present inventive concept, the electronic system 2000 may operate by using power that is supplied from the external host via the connector 2006. The electronic system 2000 may further include a power management integrated circuit (PMIC) for distributing power supplied from the external host to the main controller 2002 and the semiconductor package 2003.

The main controller 2002 may write data to the semiconductor package 2003 or read data from the semiconductor package 2003, and may increase an operating speed of the electronic system 2000.

The DRAM 2004 may act as a buffer memory for reducing a difference between operation speeds of the semiconductor package 2003 as a data storage space and the external host. The DRAM 2004 included in electronic system 2000 may operate as a cache memory, and may provide a space for temporarily storing data therein in a control operation of the semiconductor package 2003. When the DRAM 2004 is included in the electronic system 2000, the main controller 2002 may further include a DRAM controller for controlling the DRAM 2004 in addition to a NAND controller for controlling the semiconductor package 2003.

The semiconductor package 2003 may include a first semiconductor package 2003a and a second semiconductor package 2003b that are spaced apart from each other. Each of the first semiconductor package 2003a and the second semiconductor package 2003b may be embodied as a semiconductor package including a plurality of semiconductor chips 2200. Each of the first semiconductor package 2003a and the second semiconductor package 2003b may include a package substrate 2100, semiconductor chips 2200 on the package substrate 2100, adhesive layers 2300 that are disposed on a bottom face of each of the semiconductor chips 2200, a connection structure 2400 electrically connecting the semiconductor chips 2200 and the package substrate 2100 to each other, and a molding layer 2500 disposed the package substrate 2100 and covering the semiconductor chips 2200 and the connection structure 2400.

The package substrate 2100 may be embodied as a printed circuit board including package upper pads 2130. Each semiconductor chip 2200 may include an input/output pad 2210. The input/output pad 2210 may be embodied as the input/output pad 1101 in FIG. 20.

In embodiments of the present inventive concept, the connection structure 2400 may be embodied as a bonding wire that electrically connects the input/output pad 2210 and the package upper pads 2130 to each other. Accordingly, in each of the first semiconductor package 2003a and the second semiconductor package 2003b, the semiconductor chips 2200 may be electrically connected to each other in a bonding wire scheme, and may be electrically connected to the package upper pads 2130 of the package substrate 2100. In embodiments of the present inventive concept, in each of the first semiconductor package 2003a and the second semiconductor package 2003b, the semiconductor chips 2200 may be electrically connected to each other via a connection structure including a through electrode (e.g., a Through Silicon Via: TSV) instead of the connection structure 2400 using the bonding wire scheme.

In embodiments of the present inventive concept, the main controller 2002 and the semiconductor chips 2200 may be included in one package. In embodiments of the present inventive concept, the main controller 2002 and the semiconductor chips 2200 may be mounted on a separate interposer substrate different from the main substrate 2001, and the main controller 2002 and the semiconductor chips 2200 may be connected to each other via a line that is formed in the interposer substrate.

In embodiments of the present inventive concept, the package substrate 2100 may be embodied as a printed circuit board. The package substrate 2100 may include a package substrate body 2120, the package upper pads disposed on a top face of the package substrate body 2120, package lower pads 2125 disposed on a bottom face of the package substrate body 2120, or exposed through the bottom face thereof, and internal lines 2135 disposed in the package substrate body 2120 so as to electrically connect the upper pads 2130 and the lower pads 2125 to each other. The upper pads 2130 may be electrically connected to the connection structures 2400. The lower pads 2125 may be connected to the line patterns 2005 of the main substrate 2010 of the electronic system 2000 via conductive connectors 2800 as shown in FIG. 21.

In the electronic system 2000 according to embodiments of the present inventive concept, each of the semiconductor chips 2200 may include the semiconductor memory device as described above using FIGS. 1 to 7. For example, each of the semiconductor chips 2200 may include the memory cell structure CELL and the peripheral circuit structure PERI. By way of example, the memory cell structure CELL may include the first stack structure SS1, the second stack SS2, the channel structure CH, the cutting pattern WC, the through-via 166, the first wiring structure 180 and the source layer 102 as described above with reference to FIGS. 1 to 7. The peripheral circuit structure PERI may include the peripheral circuit substrate 200 and the peripheral circuit wiring structure 280. The memory cell structure CELL and the peripheral circuit structure PERI may be bonded to each other via the first bonding metal 190 and the second bonding metal 290.

While the present inventive concept has been described with reference to embodiments thereof, it will be understood by those of ordinary skill in the art that various changes in form and details may be made thereto without departing from the spirit and scope of the present inventive concept.

What is claimed is:

1. A semiconductor memory device comprising:
a substrate;
a stack structure disposed on the substrate, wherein the stack structure includes a plurality of gate electrodes stacked on each other and spaced apart from each other; and
a channel structure disposed in the stack structure and penetrating the plurality of gate electrodes,
wherein the channel structure includes:
a conductive pillar extending in a first direction that is substantially perpendicular to an upper surface of the substrate;
a channel film disposed between the plurality of gate electrodes and the conductive pillar and extending in the first direction;
a first interfacial film interposed between the conductive pillar and the channel film and extending in the first direction;
a first data storage film interposed between the conductive pillar and the first interfacial film and extending in the first direction; and
a second data storage film interposed between each of the gate electrodes and the channel film and extending in the first direction.

2. The semiconductor memory device of claim 1, wherein the first data storage film includes at least one of a ferroelectric film or an electrolyte film.

3. The semiconductor memory device of claim 1, wherein the first interfacial film includes a silicon oxide film.

4. The semiconductor memory device of claim 1, wherein the channel film includes a semiconductor material,
wherein the first interfacial film includes an oxide of the semiconductor material.

5. The semiconductor memory device of claim 1, wherein the second data storage film includes a ferroelectric film.

6. The semiconductor memory device of claim 5, further comprising a charge storage film and a third interfacial film, each of which are disposed between the second data storage film and the plurality of gate electrodes, and sequentially stacked on the second data storage film.

7. The semiconductor memory device of claim 1, wherein the second data storage film includes a tunneling insulating film, a charge storage film, and a blocking insulating film, sequentially stacked on the channel film.

8. The semiconductor memory device of claim 7, wherein each of the tunneling insulating film and the blocking insulating film includes a silicon oxide film,
wherein the charge storage film includes a silicon nitride film.

9. The semiconductor memory device of claim 7, further comprising a gate dielectric film interposed between the blocking insulating film and the plurality of gate electrodes.

10. The semiconductor memory device of claim 1, wherein the channel structure further includes:
a channel pad in contact with one end of the channel film; and
a capping insulating film interposed between the conductive pillar and the channel pad.

11. A semiconductor memory device comprising:
a peripheral circuit structure including a peripheral circuit substrate and a peripheral circuit element disposed on the peripheral circuit substrate;
a source layer including a first surface, which faces the peripheral circuit structure, and a second surface that is opposite to the first surface;
a stack structure disposed on the source layer, wherein the stack structure includes a plurality of gate electrodes stacked on top of each other and spaced apart from each other in a first direction that is substantially perpendicular to the first surface; and
a channel structure disposed on the source layer and intersecting the plurality of gate electrodes,
wherein the channel structure includes:
a conductive pillar extending in the first direction;
a channel film disposed between the plurality of gate electrodes and the conductive pillar and extending in the first direction;
a first data storage film interposed between the conductive pillar and the channel film and extending in the first direction;
a first interfacial film interposed between the channel film and the first data storage film and extending in the first direction;
a second interfacial film interposed between the plurality of gate electrodes and the channel film and extending in the first direction; and
a second data storage film interposed between the plurality of gate electrodes and the second interfacial film and extending in the first direction,
wherein the first data storage film includes at least one of a ferroelectric film or an electrolyte film.

12. The semiconductor memory device of claim 11, wherein the second data storage film includes a ferroelectric film.

13. The semiconductor memory device of claim 12, further comprising a charge storage film and a third interfacial film, each of which are disposed between the second data storage film and the plurality of gate electrodes, and sequentially stacked on the second data storage film.

14. The semiconductor memory device of claim 11, wherein the second data storage film includes a tunneling insulating film, a charge storage film, and a blocking insulating film, sequentially stacked on the channel film.

15. The semiconductor memory device of claim 14, further comprising a gate dielectric film interposed between the blocking insulating film and the plurality of gate electrodes.

16. The semiconductor memory device of claim 11, wherein the channel structure further includes:
a channel pad in contact with one end of the channel film; and
a capping insulating film interposed between the conductive pillar and the channel pad.

17. An electronic system comprising:
a main substrate;
a semiconductor memory device including a peripheral circuit structure and a cell structure sequentially stacked on the main substrate; and
a controller disposed on the main substrate and electrically connected to the semiconductor memory device,
wherein the cell structure includes:
a stack structure including a plurality of gate electrodes sequentially stacked on each other and spaced apart from each other in a first direction;
a channel structure disposed in the stack structure and penetrating the plurality of gate electrodes,
wherein the channel structure includes:
a conductive pillar extending in the first direction;
a channel film disposed between the plurality of gate electrodes and the conductive pillar and extending in the first direction;
a first interfacial film interposed between the conductive pillar and the channel film and extending in the first direction;
a second interfacial film interposed between the plurality of gate electrodes and the channel film and extending in the first direction;
a first data storage film interposed between the conductive pillar and the first interfacial film and extending in the first direction; and
a second data storage film interposed between the plurality of gate electrodes and the second interfacial film and extending in the first direction.

18. The electronic system of claim 17, wherein the controller is configured to apply different voltages to the plurality of gate electrodes and the conductive pillar, respectively.

19. The electronic system of claim 17, wherein each of the first data storage film and the second data storage film includes a ferroelectric film.

20. The electronic system of claim 17, wherein the second data storage film includes a ferroelectric film,
wherein the channel structure further includes a charge storage film and a third interfacial film, each of which are disposed between the second data storage film and the plurality of gate electrodes, and sequentially stacked on the second data storage film.
